(19) United States
(12) Patent Application Publication
(10) Pub. No.: US 2017/0040938 A1
(43) Pub. Date: Feb. 9, 2017

(54) Photovoltaic Junction Box and Photovoltaic Junction Module

(71) Applicants: Tyco Electronics (Shanghai) Co. Ltd., Shanghai (CN); Tyco Electronics Holdings (Bermuda) No. 7 Limited, Pembroke (BM)

(72) Inventors: Yuan Zhong, Shanghai (CN); Ting Tao, Shanghai (CN); Shih Ying Ko, Taipei (TW)

(73) Assignees: Tyco Electronics (Shanghai) Co. Ltd., Shanghai (CN); Tyco Electronics Holdings (Bermuda) No. 7 Limited, Pembroke (BM)

(21) Appl. No.: 15/225,906

(22) Filed: Aug. 2, 2016

(30) Foreign Application Priority Data
Aug. 4, 2015 (CN) 201510471648.1

(51) Int. Cl. H02S 40/34; H01L 31/02

(52) U.S. Cl. CPC H02S 40/34; H01L 31/0201; H01L 31/02013

(57) ABSTRACT

A photovoltaic junction box is disclosed. The photovoltaic junction box has a housing, a plurality of conduction terminals disposed in the housing, each conduction terminal having a positioning slot receiving and electrically connected to a bus bar of a solar panel, and a resilient member mounted on each conduction terminal pressing the bus bar against the conduction terminal.

### CROSS-REFERENCE TO RELATED APPLICATION

This application claims the benefit of the filing date under 35 U.S.C. §119(a)-(d) of Chinese Patent Application No. 201510471648.1 filed on Aug. 4, 2015.

### FIELD OF THE INVENTION

The present invention relates to a photovoltaic junction box, and more particularly, to a photovoltaic junction box electrically connected to a bus bar of a solar panel.

### BACKGROUND

Known photovoltaic junction boxes generally have a housing with a positive first conduction terminal, a negative second conduction terminal, a diode, and an elastic clip all disposed in the housing. The diode is connected between the positive first conduction terminal and the negative second conduction terminal. The elastic clip simultaneously clamps a positive bus bar of a solar panel to the positive first conduction terminal and a negative bus bar of the solar panel to the negative second conduction terminal, such that the positive and negative bus bars of the solar panel are electrically connected to the positive and negative second conduction terminals, respectively.

Known photovoltaic junction boxes, however, have a complicated structure with a corresponding high manufacturing cost and high level of knowledge required to use the junction box. Further, the electrical contact between the bus bar and the conduction terminal can loosen easily and does not provide a reliable connection.

### SUMMARY

An object of the invention, among others, is to provide a photovoltaic junction box with a simple structure which can form a reliable electrical connection between a bus bar of a solar panel and a conduction terminal of the photovoltaic conduction box. The disclosed photovoltaic junction box has a housing, a plurality of conduction terminals disposed in the housing, each conduction terminal having a positioning slot receiving and electrically connected to a bus bar of a solar panel, and a resilient member mounted on each conduction terminal pressing the bus bar against the conduction terminal.

### BRIEF DESCRIPTION OF THE DRAWINGS

The invention will now be described by way of example with reference to the accompanying figures, of which:

FIG. 1 is a perspective view of conduction terminals of a photovoltaic junction box according to the invention;

FIG. 2 is a perspective view of a resilient member of the photovoltaic junction box;

FIG. 3 is a perspective view of the photovoltaic junction box with the resilient member in a first position; and

FIG. 4 is a perspective view of the photovoltaic junction box with the resilient member in a second position.

### DETAILED DESCRIPTION OF THE EMBODIMENT(S)

The invention is explained in greater detail below with reference to embodiments of a photovoltaic junction box. This invention may, however, be embodied in many different forms and should not be construed as limited to the embodiments set forth herein; rather, these embodiments are provided so that this disclosure will be thorough and complete and still fully convey the scope of the invention to those skilled in the art.

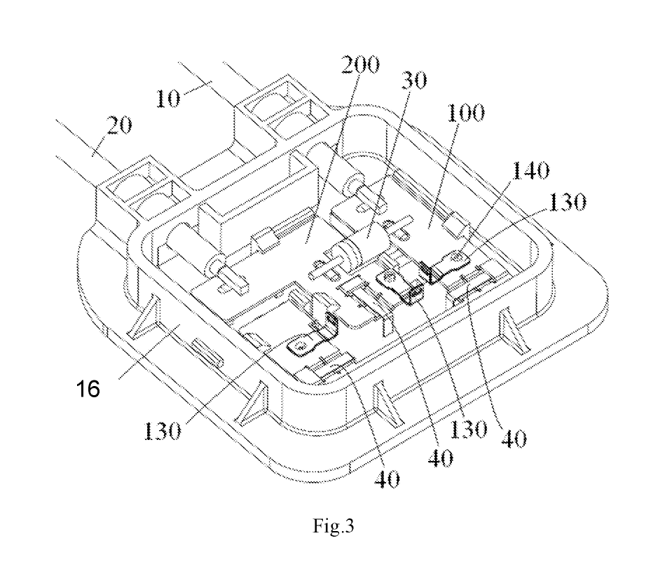

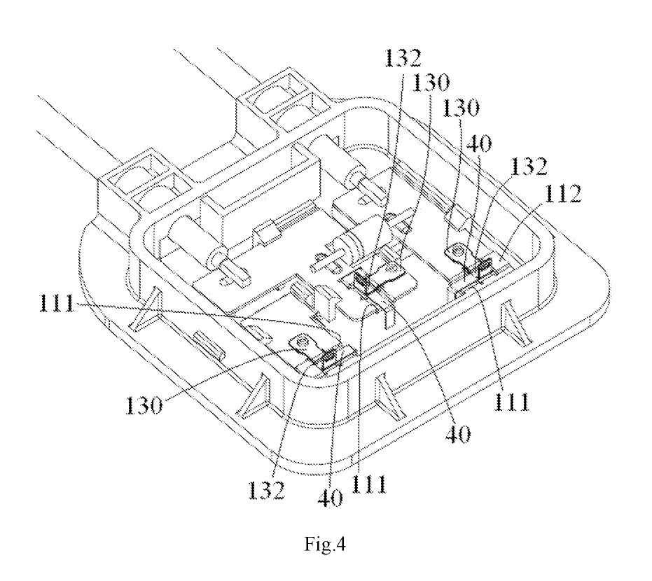

A photovoltaic junction box 1 according to the invention is shown generally in FIGS. 3 and 4. The photovoltaic junction box 1 has a housing 16, a first conduction terminal 100, a second conduction terminal 200, a plurality of resilient members 130, and a diode 30. The major components of the invention will now be described in greater detail.

The housing 16 is shown in FIG. 3. In the shown embodiment, the housing 16 is formed in a substantially square shape to enclose an interior space. One with ordinary skill in the art would understand that the housing 16 could be formed in any shape that permits the enclosure of elements of the photovoltaic junction box 1 as described herein.

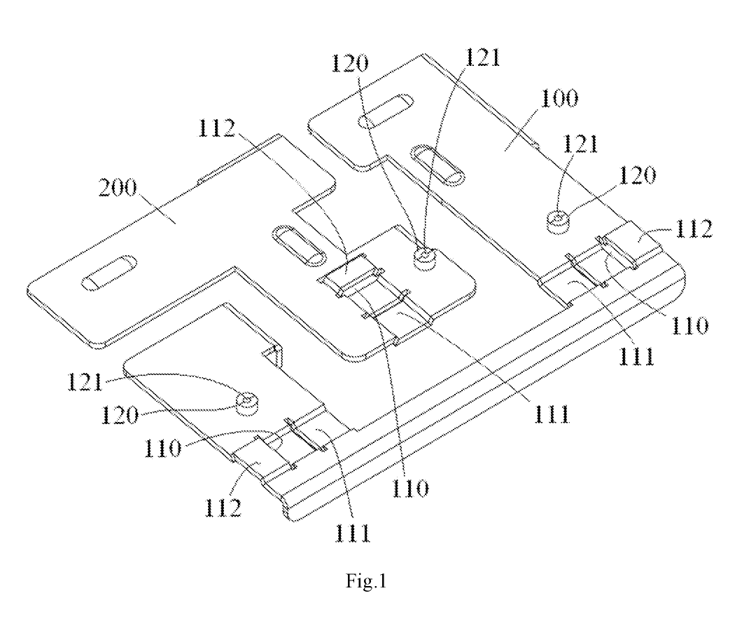

The first conduction terminal 100 and the second conduction terminal 200 are shown in FIG. 1. One of the conduction terminals 100, 200 is a positive first conduction terminal, and the other of the conduction terminals 100, 200 is a negative second conduction terminal. In the shown embodiment and for the purposes of explanation, the first conduction terminal 100 is the positive terminal, and the second conduction terminal 200 is the negative terminal. Each of the first conduction terminal 100 and the second conduction terminal 200 has at least one positioning slot 110 and at least one protrusion 120.

As shown in FIGS. 1, 3 and 4, the positioning slot 110 is defined by a recession 111 and a projection 112 both formed on a surface of the conduction terminal 100, 200 by punching. The projection 112 is formed at one end of the recession 111 and aligned with the recession 111. The recession 111 has a flat internal bottom surface lower than an upper surface of the conduction terminal 100, 200 and the projection 112 has a flat internal top surface higher than the upper surface of the conduction terminal 100, 200, the positioning slot 110 defined between the internal bottom surface of the recession 111 and the lower surface of the projection 112.

The protrusion 120 is a cylindrical projection from a surface of the conduction terminal 100, 200. The protrusion 120 has a passageway 121 positioned approximately centrally on the protrusion 120 extending through the protrusion 120.

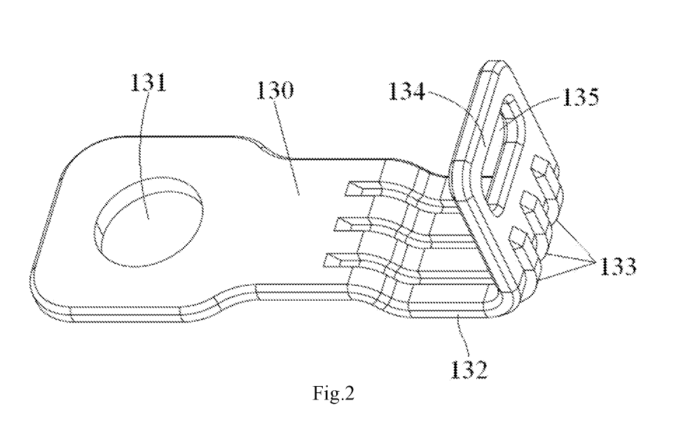

One of the plurality of resilient members 130 is shown in FIG. 2. The resilient member 130 has a through-hole 131, a pressing portion 132, a plurality of projecting ribs 133, a holding portion 134, and a slot 135. The through-hole 131 is formed in a base of the resilient member 130 at a first end of the resilient member 130, and the pressing portion 132 projects downward from the base adjacent an opposite second end of the resilient member 130. The plurality of projecting ribs 133 are separated from each other and formed on a bottom surface of the pressing portion 132. The second end of the resilient member 130 is bent upwards, and is formed with a slot 135 so as to form a holding portion 134.

The diode 30 is shown in FIG. 3. The diode 30 may be any type of diode 30 used in photovoltaic junction boxes and known to those with ordinary skill in the art.

The assembly and use of the photovoltaic junction box 1 will now be described with reference to FIGS. 3 and 4. The photovoltaic junction box 1 is shown assembled in FIGS. 3 and 4 and connected to a positive wire 10, a negative wire 20, and a plurality of bus bars 40 of a solar panel (not shown).

As shown in FIG. 3, the first conduction terminal 100, the second conduction terminal 200, the plurality of resilient members 130, and the diode 30 are disposed within the housing 16. The positive first conduction terminal 100 is arranged separated from the negative second conduction terminal 200, and the diode 30 is electrically connected between the positive first conduction terminal 100 and the negative second conduction terminal 200. The positive first conduction terminal 100 is electrically connected with the positive wire 10, and the negative second conduction terminal 200 is electrically connected with the negative wire 20.

The plurality of resilient members 130 are mounted on the conduction terminals 100, 200. Each resilient member 130 is mounted to one protrusion 120. As shown in FIGS. 3 and 4, the resilient member 130 is disposed such that the protrusion 120 extends through the through-hole 131, with the pressing portion 132 facing a surface of the conduction terminal 100, 200. The resilient member 130 is rotatably connected to the conduction terminal 100, 200 by a screw 140. The screw 140 passes through the through-hole 131 and is screwed in the passageway 121. An operator may operate the resilient member 130 through the holding portion 134, for example, by rotating the resilient member 130 between a first position shown in FIG. 3 and a second position shown in FIG. 4.

When the resilient member 130 is in the first position shown in FIG. 3, the pressing portion 132 is located outside the recession 111, and each bus bar 40 can be inserted in one positioning slot 110 on conduction terminals 100, 200. In an embodiment of the invention, the internal bottom surface of the recession 111 is provided with soldering material, such as tin solder, for soldering the bus bar 40 on the internal bottom surface of the recession 111. In this way, it is possible to prevent the bus bar 40 from moving with respect to the conduction terminal 100, 200 and to form a reliable electrical connection therebetween. The bus bar 40 may also be removed or pulled out of the positioned slot 110 when the resilient member 130 is in the first position.

One resilient member 130 and one positioning slot 110 together form a bus bar holding mechanism. When the resilient member 130 is rotated to the second position shown in FIG. 4, the pressing portion 132 is disposed in the recession 111 and presses the bus bar 40 against an internal bottom surface of the recession 111. Only the projecting ribs 133 of the pressing portion 132 press against the bus bar 40. The bus bar 40 reliably comes into electrical contact with the conduction terminal 100, 200 when pressed by the resilient member 130 and further, since only the projecting ribs 133 come into contact with the bus bar 40, the contact resistance between the resilient member 130 and the bus bar 40 is reduced.

In an embodiment of the invention, the bus bar 40 is soldered on the conduction terminal 100, 200 after the resilient member 130 is moved to the second position. Since the bus bar 40 has already been tightly pressed on the flat internal bottom surface of the recession 111 by the resilient member 130, a cold solder joint may be avoided, improving the soldering connection quality.

What is claimed is:

1. A photovoltaic junction box, comprising:
a housing;
a plurality of conduction terminals disposed in the housing, each conduction terminal having a positioning slot receiving and electrically connected to a bus bar of a solar panel; and
a resilient member mounted on each conduction terminal pressing the bus bar against the conduction terminal.

2. The photovoltaic junction box of claim 1, wherein the positioning slot is defined by a recession and a projection formed on a surface of the conduction terminal.

3. The photovoltaic junction box of claim 2, wherein the resilient member has a base and a pressing portion projecting downward from the base.

4. The photovoltaic junction box of claim 3, wherein the pressing portion presses the bus bar against an internal bottom surface of the recession.

5. The photovoltaic junction box of claim 4, wherein the resilient member is connected to the surface of the conduction terminal such that the resilient member can rotate between a first position and a second position.

6. The photovoltaic junction box of claim 5, wherein, when the resilient member is in the first position, and the pressing portion is located outside the recession.

7. The photovoltaic junction box of claim 6, wherein, when the resilient member is in the second position, the pressing portion presses the bus bar against the internal bottom surface of the recession.

8. The photovoltaic junction box of claim 7, wherein a surface of the pressing portion contacting the bus bar has a plurality of projecting ribs.

9. The photovoltaic junction box of claim 8, wherein an end of the resilient member is bent upwards and formed with a slot.

10. The photovoltaic junction box of claim 5, wherein each conduction terminal has a protrusion with a passageway extending through the protrusion.

11. The photovoltaic junction box of claim 10, wherein the resilient member has a through-hole, the resilient member rotatably connected to the conduction terminal by a screw passing through the through-hole and extending into the passageway of the protrusion.

12. The photovoltaic junction box of claim 11, wherein the recession has a flat internal bottom surface below an upper surface of the conduction terminal and the projection has a flat lower surface above the upper surface of the conduction terminal

13. The photovoltaic junction box of claim 12, wherein the projection is formed at one end of the recession and is aligned with the recession.

14. The photovoltaic junction box of claim 12, wherein the bus bar is soldered to the internal bottom surface of the recession.

15. The photovoltaic junction box of claim 1, wherein the plurality of conduction terminals includes a positive conduction terminal and a negative conduction terminal separated from the positive conduction terminal.

16. The photovoltaic junction box of claim 15, further comprising a diode electrically connecting the positive conduction terminal and the negative conduction terminal.

17. The photovoltaic junction box of claim 15, further comprising a positive wire electrically connected to the positive conduction terminal and negative wire electrically connected to the negative conduction terminal.

18. A photovoltaic connection module, comprising:
a photovoltaic junction box having a housing, a plurality of conduction terminals disposed in the housing each having a positioning slot, and a resilient member mounted on each conduction terminal; and
a solar panel having a plurality of bus bars, each bus bar inserted in one positioning slot and pressed by one resilient member to electrically contact one conduction terminal.

19. The photovoltaic connection module of claim 18, wherein the bus bar is soldered to an internal bottom surface of the positioning slot.

20. A method of manufacturing a photovoltaic connection module, comprising:
providing a photovoltaic junction box having a housing, a plurality of conduction terminals disposed in the housing each having a positioning slot, and a resilient member mounted on each conduction terminal;
inserting a bus bar of a solar panel in the positioning slot;
positioning the resilient member to press the bus bar against the conduction terminal; and
soldering the bus bar to the conduction terminal after pressing the bus bar against the conduction terminal.
